(19) United States
(12) Patent Application Publication
(10) Pub. No.: US 2013/0207275 A1
(43) Pub. Date: Aug. 15, 2013

(54) Methods of Forming Device Level Conductive Contacts to Improve Device Performance and Semiconductor Devices Comprising Such Contacts

(71) Applicants: Ricardo P. Mikalo, Heideblick (DE); Thilo Scheiper, Dresden (DE); Stefan Flachowsky, Dresden (DE)

(72) Inventors: Ricardo P. Mikalo, Heideblick (DE); Thilo Scheiper, Dresden (DE); Stefan Flachowsky, Dresden (DE)

(73) Assignee: GLOBALFOUNDRIES INC., Grand Cayman (KY)

(21) Appl. No.: 13/397,199

(22) Filed: Feb. 15, 2012

(51) Int. Cl. H01L 23/48

(52) U.S. Cl. 257/774; 257/E23.011

(57) ABSTRACT

Disclosed herein are various methods of forming device level conductive contacts to improve device performance and various semiconductor devices with such improved deice level contact configurations. In one example, a device disclosed herein includes a first device level conductive contact positioned in a first layer of insulating material, wherein the first device level conductive contact is conductively coupled to a semiconductor device, a second device level conductive contact positioned above and conductively coupled to the first device level contact, wherein the second device level contact is positioned in a second layer of insulating material, and a first wiring layer for the device that is positioned above and conductively coupled to the second device level conductive contact.

### BACKGROUND OF THE INVENTION

1. Field of the Invention

Generally, the present disclosure relates to the manufacturing of sophisticated semiconductor devices, and, more specifically, to various methods of forming device level conductive contacts to improve device performance and to various semiconductor devices with such improved device level contact configurations.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein field effect transistors (NMOS and PMOS transistors) represent one important type of circuit element that substantially determines performance of the integrated circuits. During the fabrication of complex integrated circuits using, for instance, MOS technology, millions of transistors, e.g., NMOS transistors and/or PMOS transistors, are formed on a substrate including a crystalline semiconductor layer. A field effect transistor, irrespective of whether an NMOS transistor or a PMOS transistor is considered, typically comprises so-called PN junctions that are formed by an interface of highly doped regions, referred to as drain and source regions, with a slightly doped or non-doped region, such as a channel region, disposed between the highly doped source/drain regions. The channel length of a MOS transistor is generally considered to be the lateral distance between the source/drain regions.

FIG. 1 is an illustrative prior art device 100 comprised of a plurality of illustrative transistors 12 formed in and above a semiconducting substrate 10. The transistors 12 are intended to be representative in nature. In general, the transistors 12 are comprised of a gate insulation layer 12A, a gate electrode 12B and sidewall spacers 13. Illustrative source/drain regions 16 for the transistors 12 are formed in the substrate 10. Of course, as will be recognized by those skilled in the art, various aspects of a real-world transistor are not depicted in FIG. 1, e.g., metal silicide contacts, isolation regions, etc. A device level conductive contact 18, a contact that is conductively coupled to the illustrative transistor device 12, is formed in a layer of insulating material 14. In a typical prior art device, the layer of insulating material 14 may have a thickness of about 150 nm while the overall height of the gate structure may be about 60 nm. A first metal wiring layer 20, typically referred to as “metal 1” is formed above the layer of insulating material 14. There are various parasitic capacitances that can adversely affect transistor performance as such capacitances are charged and discharged in each on-off switching cycle which slows down the operating speed of the device. With reference to FIG. 1, among these parasitic capacitances are the Gate-Overhang capacitance (C_{OV}), the Gate-Fringe capacitance (C_{F}), the Gate-Contact capacitance (C_{CO}) and the Gate-Metal 1 capacitance (C_{GM1}).

Device designers are under constant pressure to increase the operating speed and electrical performance of transistors and integrated circuit products that employ such transistors. In some cases, customers demand that manufacturers produce integrated circuit products with periodic and significant performance improvement while maintaining the footprint of earlier generation devices so as to limit the amount of re-design the customer has to do to the end product. Over the past 10-15 years, device designers have been very successful at achieving significant and periodic improvement in the performance of semiconductor devices, such as microprocessors, by shrinking or scaling various aspects of the devices, such as the gate length on transistors. Given that the gate length (the distance between the source and drain regions) on modern transistor devices may be approximately 30-50 nm, and that further scaling is anticipated in the future, device designers have employed a variety of techniques in an effort to improve device performance, e.g., the use of high-k dielectrics, the use of metal gate electrode structures, the incorporation of work function metals in the gate electrode structure and the use of channel stress engineering techniques on transistors (create a tensile stress in the channel region for NMOS transistors and create a compressive stress in the channel region for PMOS transistors). However, using device shrinkage techniques to achieve significant device performance improvement is becoming more difficult as the size of the devices continues to shrink. Nevertheless, customers still continue to demand integrated circuit products that exhibit increased device performance.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming device level conductive contacts to improve device performance and to various semiconductor devices with such improved device level contact configurations. In one example, a device disclosed herein includes a first device level conductive contact positioned in a first layer of insulating material, wherein the first device level conductive contact is conductively coupled to a semiconductor device, a second device level conductive contact positioned above and conductively coupled to the first device level contact, wherein the second device level contact is positioned in a second layer of insulating material, and a first wiring layer for the device that is positioned above and conductively coupled to the second device level conductive contact.

Another illustrative device disclosed herein includes a first device level conductive contact that is positioned in a first layer of insulating material, wherein the first device level conductive contact is conductively coupled to a semiconductor device, and a second device level conductive contact that is positioned above and conductively coupled to the first device level contact, wherein the second device level contact is positioned in a second layer of insulating material. In this illustrative embodiment, the first and second device level contacts are the same size and they are comprised of the same material. The device further includes a first wiring layer for the device that is positioned above and conductively coupled to the second device level conductive contact.

Yet another illustrative device disclosed herein includes a first device level conductive contact that is positioned in a first layer of insulating material, wherein the first device level conductive contact is conductively coupled to a semiconductor device, and a second device level conductive contact that is positioned above and conductively coupled to the first device level contact, wherein the second device level contact is positioned in a second layer of insulating material. In this illustrative embodiment, the first and second device level contacts are different sizes and they are comprised of the same material. The device father includes a first wiring layer for the device that is positioned above and conductively coupled to the second device level conductive contact.

### BRIEF DESCRIPTION OF THE DRAWINGS

The disclosure may be understood by reference to the following description taken in conjunction with the accompanying drawings, in which like reference numerals identify like elements, and in which:

FIG. 1 depicts one illustrative prior art semiconductor device with conductive contacts formed thereon;

FIG. 2 depicts one illustrative device disclosed herein that includes device level contacts that may improve device performance characteristics;

FIG. 3 depicts another illustrative device disclosed herein that includes device level contacts that may improve device performance characteristics; and

FIG. 4 depicts yet another illustrative device disclosed herein that includes device level contacts that may improve device performance characteristics

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of forming device level conductive contacts to improve device performance and to various semiconductor devices with such improved device level contact configurations. As will be readily apparent to those skilled in the art upon a complete reading of the present application, the present method is applicable to a variety of technologies, e.g., NMOS, PMOS, CMOS, etc., and is readily applicable to a variety of devices, including, but not limited to, ASIC's, logic devices, memory devices, etc. With reference to the attached drawings, various illustrative embodiments of the methods disclosed herein will now be described in more detail.

FIG. 2 is a simplified view of an illustrative semiconductor device 200 at an early stage of manufacturing that is formed above a semiconducting substrate 210. The substrate 210 may have a variety of configurations, such as the depicted bulk silicon configuration. The substrate 210 may also have a silicon-on-insulator (SOI) configuration that includes a bulk silicon layer, a buried insulation layer and an active layer, wherein semiconductor devices are formed in and above the active layer. Thus, the terms substrate or semiconductor substrate should be understood to cover all forms of semiconductor structures. The substrate 210 may also be made of materials other than silicon.

At the point of fabrication depicted in FIG. 2, the device 200 includes a plurality of illustrative transistors 202 formed in and above the semiconducting substrate 210. The transistors 202 are intended to be representative in nature. In the depicted example, the transistors 202 are comprised of a gate insulation layer 202A, a gate electrode 202B and sidewall spacers 204. Illustrative source/drain regions 216 for the transistors 202 are formed in the substrate 210. The device 200 also includes a first layer of insulating material 214A and a second layer of insulating material 214B formed above the substrate 210. Although not depicted in FIG. 2, in some applications, an etch stop or polish stop layer, such as silicon nitride, may be formed between the first and second layers of insulating material 214A, 214B. A first device level conductive contact 218A is formed in the first layer of insulating material 214A and a second device level contact 218B is formed in the second layer of insulating material 214B. A first metal wiring layer 220, typically referred to as “metal 1”, is formed above the second layer of insulating material 214B. In general, as used herein and in the claims, the phrase “device level contact” shall be understood to refer to conductive contacts that are positioned between the metal 1 layer 220 and the semiconductor devices, e.g., the illustrative transistors 202. At least some of the various parasitic capacitances that can adversely affect the performance of the transistors 202 are also depicted in FIG. 2: the Gate-Overhang capacitance (C_{OV}), the Gate-Fringe capacitance (C_{F}), the Gate-Contact capacitance (C_{CO}) and the Gate-Metal 1 capacitance (C_{GM1}).

The various components and structures of the device 200 may be formed using a variety of different materials and by performing a variety of known techniques. For example, the gate insulation layer 202A may be comprised of a variety of different insulating materials, e.g., silicon dioxide, a so-called high-k insulating material (k value greater than 10). The gate electrode 202B may be comprised of polysilicon or it may contain at least one metal layer. The gate structure of the transistors 202 may be made using so-called “gate first” or “gate last” techniques. The sidewall spacers 204 may be comprised of a variety of materials, such as silicon nitride. The first and second layers of insulating material 214A, 214B may be made of a variety of different materials, e.g., silicon dioxide, a low-k material (k value less than 3), organic insulating compounds (e.g., parylene), etc., and the first and second layers of insulating material 214A, 214B need not be made of the same material and they need not have the same thickness, although they may in some applications. The first and second device level conductive contacts 218A, 218B as well as the metal 1 layer 220 may be comprised of a variety of different materials, such as, for example, copper, tungsten, aluminum, carbon nanotubes, graphite, gold, etc., and these conductive structures 218A, 218B and 220 need not all be made of the same material, although they may be in some applications. The first and second device level conductive contacts 218A, 218B need not be of the same size and configuration although that may be the case in some applications. In one illustrative embodiment, the first and second device level conductive contacts 218A, 218B may be approximately square posts having a nominal dimension of about 40 nm×40 nm. In one illustrative example, the first and second layers of insulating material 214A, 214B may be comprised of silicon dioxide and they both may have a thickness of about 150-200 nm. The source/drain regions 216 may be comprised of implanted dopant materials (N-type dopants for NMOS devices and P-type dopant for PMOS devices) that are implanted into the substrate 210 using known masking and ion implantation techniques.

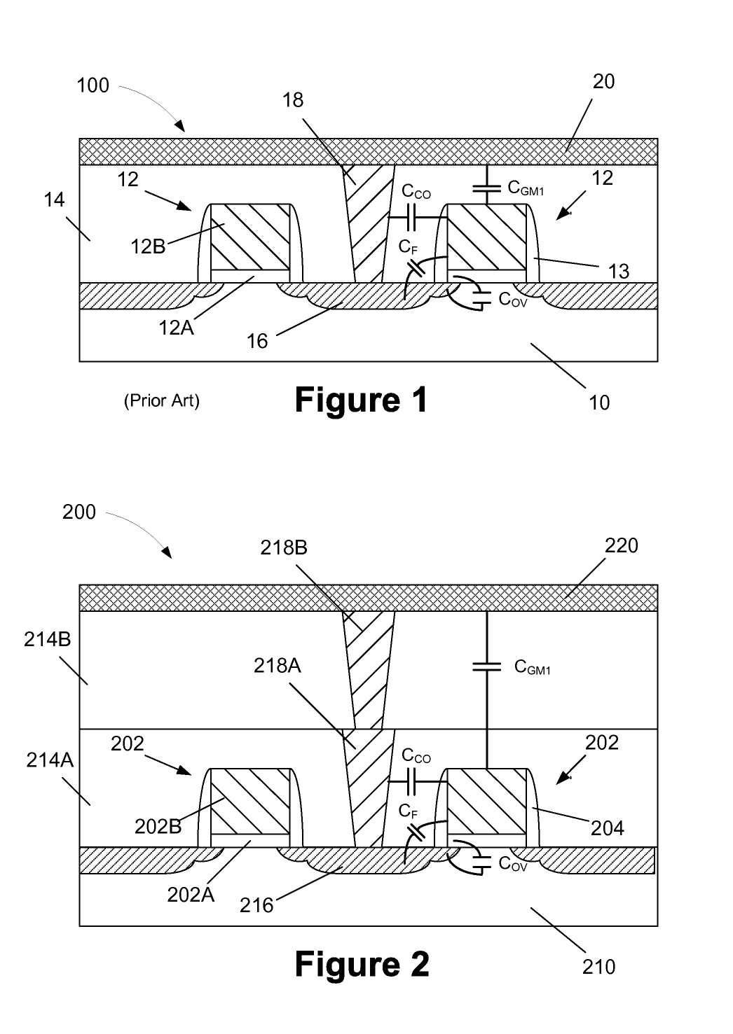

In contrast to the prior art device 100 depicted in FIG. 1, the use of two or more levels of device level contacts has the desired effect of reducing the magnitude of the Gate-Metal 1 capacitance (C_{GM1}) due to the larger vertical spacing between the gate structures of the transistors 202 and the metal 1 layer 220. In one illustrative example, where the insulating layer 14 in the prior art device 100 has a thickness of about 150 nm, and the height of the gate structures of the transistors 12 was about 60 nm, the spacing between the gate structures of the transistors 12 and the metal 1 layer 20 shown in FIG. 1 was about 90 nm (150-60 nm). In contrast, in the illustrative embodiment of the device 200 where the first and second layers of insulating material 214A, 214B both have a thickness of about 150 nm and the gate structures of the transistors 202 have a height of about 60 nm, the spacing between the gate structures of the transistors 202 and the metal 1 layer 220 shown in FIG. 2 is about 240 nm (300-60 nm). Using the novel structure depicted in FIG. 2, in this illustrative example, the Gate-Metal 1 capacitance (C_{GM1}) of the device 200 is approximately 80-90% less than the Gate-Metal 1 capacitance (C_{GM1}) of the illustrative prior art device 100 depicted in FIG. 1.

Electrical estimates as to the reduction in the Gate-Metal 1 capacitance (C_{GM1}) for the device 200 depicted in FIG. 2 as compared to the Gate-Metal 1 capacitance (C_{GM1}) of the illustrative prior art device 100 depicted in FIG. 1 were made, and the impact such reduction in the Gate-Metal 1 capacitance (C_{GM1}) would have as it relates to improving the operational performance of the device 200 as compared to the operational performance of the illustrative prior art device 100 depicted in FIG. 1. Based upon electrical simulation, it was determined that a reduction in the Gate-Contact capacitance (C_{CO}) of about 70 aF/μm resulted in a speed gain of about 150 MHz for a prior art ring oscillator running at about 2.2 GHz. As a conservative estimate, it is believed that the novel structures 200 disclosed herein can reduce the Gate-Metal 1 capacitance (C_{GM1}) by about 35 aF/μm. Based upon the aforementioned electrical simulation for the Gate-Contact capacitance (C_{CO}), it is believed that the device 200 depicted in FIG. 2 would produce an equivalent speed gain of about 75 MHz as compared to the illustrative prior art device 100 depicted in FIG. 1.

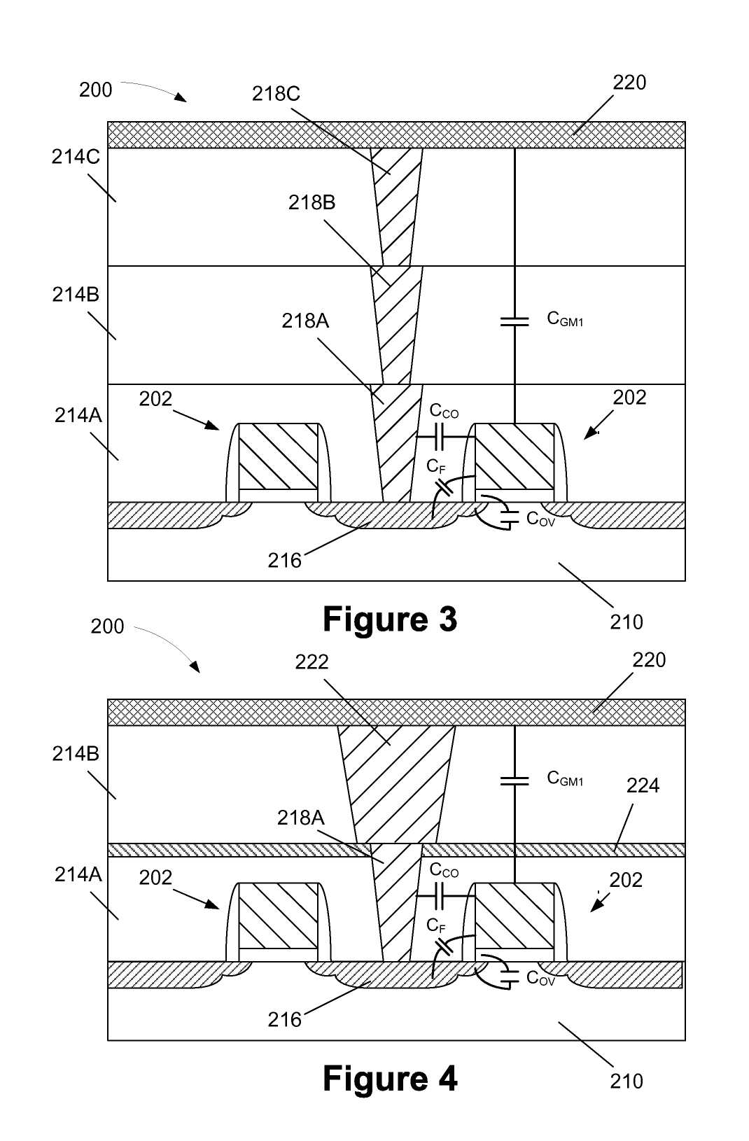

FIG. 3 depicts another illustrative embodiment of the device 200 wherein three illustrative levels of the conductive device level contacts have been formed to further increase the distance between the gate structures of the transistors 202 and the metal 1 layer 220 to thereby decrease the magnitude of the Gate-Metal 1 capacitance (C_{GM1}) of the illustrative device 200 depicted in FIG. 3 as compared to the device 200 depicted in FIG. 2. More specifically, illustrative conductive device level contacts 218A, 218B and 218C have been formed in first, second and third layers of insulating material 214A, 214B and 214C, respectively. As before, the first, second and third layers of insulating material 214A, 214B and 214C may be made of a variety of different insulating materials, and the first, second and third layers of insulating material 214A, 214B and 214C need not be made of the same material and they need not have the same thickness, although they may in some applications. Similarly, the first, second and third device level conductive contacts 218A, 218B and 218C as well as the metal 1 layer 220 may be comprised of a variety of different conductive materials, and these conductive structures 218A, 218B, 218C and 220 need not all be made of the same material, although they may be in some applications. The first, second and third device level conductive contacts 218A, 218B and 218C need not be of the same size and configuration although that may be the case in some applications. In one illustrative embodiment, the first, second and third device level conductive contacts 218A, 218B and 218C may be approximately square posts having a nominal dimension of about 40 nm×40 nm. In one illustrative example, the first, second and third layers of insulating material 214A, 214B and 214C may each be comprised of silicon dioxide and they may each have a thickness of about 150-200 nm. The electrical simulation information discussed above would apply equally to the device 200 depicted in FIG. 3, and perhaps better performance enhancement would be expected from the device 200 depicted in FIG. 3 due to the use of three levels of conductive device level contacts.

FIG. 4 depicts yet another illustrative embodiment of the device 200. In this illustrative example, as compared to the device 200 depicted in FIG. 2, a relatively oversized device level contact 222 is formed in the second layer of insulating material 214B. Additionally, an illustrative etch stop layer 224 is formed on the first layer of insulting material. As before, the first device level conductive contacts 218A and the oversized device level conductive contact 222 need not be made of the same material, although that may be the case in some applications. In one illustrative example, where the first device level conductive contacts 218A may be approximately square posts having a nominal dimension of about 40 nm×40 nm, the oversized device level conductive contact 222 may be approximately square posts having a nominal dimension of about 50 nm×50 nm. In an ideal situation, the bottom footprint of the oversized device level conductive contact 222 should be kept relatively small. Although no electrical stimulation of the device depicted in FIG. 4 has been performed, the inventors believe that such an electrical simulation would show that the Gate-Metal 1 capacitance (C_{GM1}) of the device 200 shown in FIG. 4 would be approximately 60-70% less than the Gate-Metal 1 capacitance (C_{GM1}) of the illustrative prior art device 100 depicted in FIG. 1. Additionally, the relatively larger upward-flaring of the oversized device level conductive contact 222 would make fabrication of the device more efficient and cheaper as compared to other contact arrangements. An increase in capacitance due to this upward-flaring of the oversized device level conductive contact 222 would be relatively negligible as compared to the other benefits such a configuration provides.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A device, comprising:
a first device level conductive contact positioned in a first layer of insulating material, said first device level conductive contact being conductively coupled to a semiconductor device;
a second device level conductive contact positioned above and conductively coupled to said first device level contact, said second device level contact being positioned in a second layer of insulating material; and
a first wiring layer for said device positioned above and being conductively coupled to said second device level conductive contact.

2. The device of claim 1, wherein said device is a transistor.

3. The device of claim 1, wherein said first and second device level contacts are the same size.

4. The device of claim 1, wherein said first and second device level contacts are comprised of the same material.

5. The device of claim 1, wherein said second device level contact is larger than said first device level contact.

6. The device of claim 1, wherein said first and second layers of insulating material have the same thickness.

7. The device of claim 1, wherein said first and second layers of insulating material are comprised of the same material.

8. The device of claim 1, further comprising a third device level conductive contact positioned above and conductively coupled to said second device level contact, said third device level contact being positioned in a third layer of insulating material, wherein said first wiring layer is positioned above and conductively coupled to said third device level conductive contact.

9. A device, comprising:
a first device level conductive contact positioned in a first layer of insulating material, said first device level conductive contact being conductively coupled to a semiconductor device;
a second device level conductive contact positioned above and conductively coupled to said first device level contact, said second device level contact being positioned in a second layer of insulating material, wherein said first and second device level contacts are the same size and wherein said first and second device level contacts are comprised of the same material; and
a first wiring layer for said device positioned above and being conductively coupled to said second device level conductive contact.

10. The device of claim 9, wherein said first and second layers of insulating material have the same thickness.

11. The device of claim 9, wherein said first and second layers of insulating material are comprised of the same material.

12. The device of claim 9, further comprising a third device level conductive contact positioned above and conductively coupled to said second device level contact, said third device level contact being positioned in a third layer of insulating material, wherein said first wiring layer is positioned above and conductively coupled to said third device level conductive contact.

13. A device, comprising:
a first device level conductive contact positioned in a first layer of insulating material, said first device level conductive contact being conductively coupled to a semiconductor device;
a second device level conductive contact positioned above and conductively coupled to said first device level contact, said second device level contact being positioned in a second layer of insulating material, wherein said second device level contact is larger than said first device level contact and wherein said first and second device level contacts are comprised of the same material; and
a first wiring layer for said device positioned above and being conductively coupled to said second device level conductive contact.

14. The device of claim 13, wherein said first and second layers of insulating material have the same thickness.

15. The device of claim 13, wherein said first and second layers of insulating material are comprised of the same material.

16. The device of claim 13, further comprising a third device level conductive contact positioned above and conductively coupled to said second device level contact, said third device level contact being positioned in a third layer of insulating material, wherein said first wiring layer is positioned above and conductively coupled to said third device level conductive contact.
